(19) United States
(12) Patent Application Publication
(10) Pub. No.: US 2016/0370418 A1
(43) Pub. Date: Dec. 22, 2016

(54) MONITORING MODULE FOR PROTECTIVE-CONDUCTOR MONITORING

(71) Applicant: Wilfried PÖLLET, Schwanstetten (DE)

(72) Inventor: Wilfried Pöllet, Schwanstetten (DE)

(21) Appl. No.: 15/121,555

(22) PCT Filed: Feb. 27, 2015
(86) PCT No.: PCT/EP2015/054204

§ 371 Date: Aug. 25, 2016

(30) Foreign Application Priority Data
Feb. 28, 2014 (DE) 20 2014 100 930.2
Mar. 18, 2014 (DE) 20 2014 101 250.8
Apr. 17, 2014 (EP) 14165242.0

(51) Int. Cl. G01R 31/04

(52) U.S. Cl. CPC G01R 31/04

(57) ABSTRACT

A monitoring module for protective-conductor monitoring has a monitoring circuit, by way of which it is checked whether a protective conductor is properly connected. If a protective-conductor interruption is detected, the monitoring circuit identifies this as a first fault case and outputs a first fault signal. The monitoring circuit is designed additionally to store the first fault case and outputs a second fault signal in the event of an only temporary protective-conductor interruption that is no longer present. By this measure, improved protection of persons is achieved, even in the event of, for example, intermittent contacts, etc.

The invention relates to a monitoring module for protective conductor monitoring, comprising a monitoring circuit for monitoring whether a protective conductor is properly connected, in which case, if a protective conductor interruption is detected, the monitoring circuit identifies this as a first fault and outputs a first fault signal.

Such a monitoring module is described in EP 0 778 467 A2, for example. The circuit arrangement which can be gathered therefrom comprises a phase connection for a phase conductor, a neutral connection for a neutral conductor and a PE connection for a protective conductor to be monitored. The phase connection and the neutral connection are connected to one another via a capacitive voltage divider. The PE connection, on the one hand, and an evaluation circuit, on the other hand, are connected to the center tap of the voltage divider, via which evaluation circuit the voltage value present at this center tap is tapped off and evaluated. The PE voltage which has been tapped off is compared with the predefined threshold value with the aid of a comparator. If the protective conductor is properly connected, the PE connection and the neutral connection are usually at the at least approximately same ground potential, with the result that the PE voltage applied to the center tap is very low and is below the threshold value. If a protective conductor is not properly connected, that is to say if it is interrupted, a considerably higher voltage value for the PE voltages is present in contrast at the center tap on account of the voltage divider function, which is identified as a fault via the comparator since the threshold value which has been set is then exceeded.

In this case, an alarm signal can then be output. This circuit arrangement is generally used for protection for dangerous body currents since it is detected in good time whether a protective conductor is properly connected. In this case, the circuit arrangement described in EP 0 787 467 A2 is used, in particular, to monitor an electrically operated Jacuzzi.

A further monitoring circuit for protective conductor monitoring can be gathered from EP 2 626 965 A1. This is used for integration in a power line extension, for example a cable drum, in order to be able to check whether the protective conductor is properly connected to ground potential. In this circuit, a check is carried out in order to determine whether a current flows via the protective conductor connection (PE connection). In this case, it is assumed that, if correctly connected, at least a small current flows via the protective conductor in each operating state and can then be measured. If the protective conductor is interrupted, a current therefore no longer flows. In addition to outputting an acoustic or optical alarm signal, EP 2626965 A1 also provides for the power supply to be disconnected.

On the basis of this, the invention is based on the object of specifying an improved monitoring module for protective conductor monitoring.

The object is achieved, according to the invention, by means of a monitoring module having the features of claim 1 and claim 2. The further subclaims contain preferred configurations and developments.

The combination of features stated in claim 1 specifies a combination of features according to the invention of a standard monitoring module, as used, in particular, for a variable electrification system, in particular for offices. Claim 1 is formed by a combination of a plurality of the following claims which are discussed in more detail below.

In order to monitor whether a protective conductor is properly connected, the monitoring module according to the invention as claimed in claim 2 has a monitoring circuit which, if a protective conductor interruption is detected, identifies it as a first fault and outputs a first fault signal. A properly connected protective conductor is generally understood as meaning the fact that a protective conductor of a power supply network is connected to ground potential. In installation networks of buildings, the protective conductor and the neutral conductor are usually electrically connected to one another on the input side of the installation, that is to say at a supply input for the entire building, with the result that the protective conductor and the neutral conductor are usually at an at least approximately identical potential. If the protective conductor is not properly connected, an electrical connection to the ground potential is therefore no longer present.

The monitoring module is also designed to store the first fault, to be precise in such a manner that, in the event of an only temporary protective conductor interruption which is no longer present, this is identified as a second temporary fault, and a second fault signal which differs from the first fault signal is output. In this case, the second fault signal is preferably a combined fault signal which indicates both a current proper state and also indicates that a first fault has existed. Provision is also made for a signal to be output in the proper state, which signal indicates this proper state, in particular a green signal lamp, for example. In addition, a further signal luminaire, for example an orange or red luminaire, is activated for the purpose of indicating the second, temporary fault.

A decisive aspect of this configuration can be seen in the fact that storage is effected if a fault occurs and, if the first fault disappears, virtually two operating states are indicated, namely the current OK state and the faulty state in the past. This configuration is based on the consideration that the problem of a protective conductor interruption being caused by a loose contact, for example, with the result that the protective conductor is interrupted or connected to ground potential again and again, exists in certain applications. This state is also a fault since the permanently proper connection to the ground potential is not ensured.

The monitoring module is fundamentally designed for permanent, lasting monitoring, that is to say does not need to be additionally activated for the monitoring function. This ensures that temporary disruptions are also reliably detected.

This is particularly important, in particular in the case of variable electrification systems in which individual desks are supplied using socket power systems. This is because problems often occur here by virtue of the fact that the cables are laid on the floor, for example, across which office chairs then repeatedly move, which can result in a line break. The problem of cables being jammed etc. also often occurs. In such cases, the monitoring modules according to the invention fundamentally ensure that the user receives an alarm notification that a problem has at least temporarily arisen with the protective conductor.

In this case, provision is expediently also made for the monitoring circuit to be designed in such a manner that this temporary fault is permanently stored until a manual reset. Therefore, it is necessary to deliberately actively disconnect the fault, which additionally contributes to safety. The corresponding memory is therefore designed to permanently store the temporary fault. The manual reset is carried out, for example, by interrupting the supply voltage for the monitoring module.

With regard to efficient monitoring with various functions, in particular also the storage function, the monitoring circuit is provided with a microcontroller which identifies at least the first fault. In addition, the microcontroller is also designed to store the first fault in the event of a temporary fault. In this case, the microcontroller is designed, in particular, to evaluate voltage values present at its input.

In this case, the monitoring circuit is designed, in particular, to evaluate a PE voltage applied to a PE connection. The different faults also described below are identified on the basis of the voltage value of the PE voltage.

Overall, the monitoring circuit has for this purpose, on the input side, a phase connection for a phase conductor with an adjoining phase path, a PE connection for the protective conductor to be monitored with an adjoining PE path and a neutral connection for a neutral conductor with an adjoining neutral path. In order to check a PE voltage applied to the PE path for the presence of at least the first fault, the monitoring circuit also has an evaluation unit, in particular the microcontroller mentioned. This evaluation unit has a PE input and is designed to compare the PE voltage with a first voltage reference value.

In this case, the PE voltage is expediently tapped off at a center tap of a voltage divider formed between the phase path and the neutral path and is evaluated as the PE voltage. In this respect, the monitoring circuit is similar to the circuit described in EP 0 778 467 A2. An important difference can already be seen in the fact that a microcontroller is integrated in the circuit arrangement according to the invention. In addition to the option of storing the first fault, a particular advantage of the microcontroller can also be seen in the fact that different threshold values can be predefined in order to identify different faults. The voltage monitoring of the voltage applied to the PE path, which is implemented by means of this monitoring circuit, has proved to be particularly efficient and robust in comparison with checking a current which possibly flows via the protective conductor.

In one preferred development, in order to be able to check the functionality of the monitoring circuit, the monitoring module has an interrupter which can be manually actuated and, for the purpose of simulating an interrupted protective conductor, is designed to temporarily interrupt the PE path. Therefore, the interrupter is designed like a switch which interrupts the connection between the PE path and the ground potential. For this purpose, the interrupter is arranged, in particular, in the region between the PE connection and the center tap of the voltage divider.

The evaluation unit also expediently has a test input which is connected to the interrupter via a test path. In this case, a connection between the test path and the center tap of the voltage divider is established if the interrupter is actuated. As a result of this measure, the voltage is therefore applied to the center tap, that is to say the PE voltage is applied both to the PE input and to the test input of the evaluation unit. On account of the manual interruption by the manual interrupter, the voltage is usually increased at the center tap, which is identified as a first fault. At the same time, this voltage is also detected at the test input.

The evaluation unit is expediently designed, in particular, to identify this first fault triggered by the interrupter using this voltage applied to the test input. In this case, the first fault is not stored and a second fault signal is not output.

In an expedient development, the monitoring module overall is also designed to detect further faults. This is either a third fault, in which a voltage is applied to the PE connection, or a fourth fault, in which the polarity of the phase connection and of the neutral connection is reversed.

The third fault occurs, for example, if the phase of the supply network is at the PE connection on account of incorrect installation. Under certain circumstances, there is the risk here of the conventional safety measures, for example overcurrent circuit breakers or else residual current circuit breakers, not being effective. However, this problem also arises, for example, when a housing of an electrical device is connected to the protective conductor and, at the same time, the phase conductor is connected to the metal housing on account of a defect or faulty connection. Detecting this additional, third fault therefore achieves protection which is additionally improved again.

Alternatively or additionally, it is also detected whether the polarity of the phase connection and of the neutral connection is reversed, that is to say whether or not the phase of the supply network is applied to the neutral connection. In a preferred development, for this further fault, the evaluation unit stores a second voltage reference value, the exceeding of which indicates the further fault. In this case, this second voltage reference value is greater than the first voltage reference value. In this case, the PE voltage applied to the PE input of the microcontroller is preferably evaluated again. In this case, this configuration is based on the consideration that in both cases, that is to say both when the polarity is reversed and when a voltage is applied to the PE connection, the voltage value at the center tap is considerably higher in comparison with the first fault, with the result that these two further faults can be clearly distinguished from the first fault.

If the further fault is detected, a further fault signal is expediently output, which signal identifies this further fault and is characteristic of the latter.

Since, in the one embodiment variant described here, polarity reversal and a voltage applied to the PE connection are identified as the same fault, it is necessary for the user to reverse the polarity as a first measure, for example by rotating a plug through 180°, in order to check whether the further fault is caused by polarity reversal. If the further fault is still indicated, voltage is applied to the PE connection and a safety measure must be taken immediately.

In an alternative configuration, the circuit arrangement is preferably designed in such a manner that it detects polarity reversal, but does not output this as a fault, but rather continues to monitor whether the protective conductor is properly connected. For this purpose, the evaluation unit is additionally also designed to check the voltage value present at the phase connection or neutral connection. If polarity reversal is identified, a modified voltage reference value is used as the first voltage reference value for monitoring for the first fault. This configuration is based on the fact that, in the event of polarity reversal, the voltage measured at the PE input in the microcontroller is characteristically changed. The voltage at the microcontroller is regularly measured against a basic potential, this basic potential usually being at least approximately defined by the potential present at the neutral conductor. In the event of polarity reversal, the reference potential, with respect to which the voltage at the PE input is determined, is therefore a high potential at least in the vicinity of the conventional operating voltage. Therefore, a high voltage difference is determined at the PE input in the case of a proper protective conductor and in the event of polarity reversal. If the PE conductor is interrupted, a voltage which is reduced in comparison is measured in the event of the first fault. Therefore, the modified voltage reference value correlates to a voltage value which is some 10 volts below the normal mains voltage, for example. If the modified voltage reference value is undershot, the first fault is then detected. In this respect, a logic unit is therefore implemented inside the monitoring module, in particular inside the microcontroller, which logic unit detects polarity reversal and accordingly sets a dynamic voltage threshold for the first fault using the voltage reference value. A dynamic voltage threshold is understood as meaning the fact that it automatically changes over to the modified voltage reference value in the event of polarity reversal.

In a preferred configuration, the evaluation unit is supplied with voltage during normal operation via the mains voltage. For this purpose, the monitoring circuit therefore contains a supply module which extracts the supply voltage for the monitoring module, in particular for the microcontroller and for the individual signal generators, from the mains voltage and provides said supply voltage. In an expedient embodiment, a battery is also additionally provided as the emergency power supply. Such an emergency power supply is required, in particular, when the phase is connected to the PE connection as a result of a faulty connection. In this case, the supply module would be dead. Therefore, reliable functionality of the monitoring module is also ensured in this special fault as a result of the additional battery for the emergency power supply.

Different characteristic fault signals are output for the different faults. For this purpose, the monitoring module has a plurality of signal generators. It expediently has a plurality of signal generators of different types, namely light signal generators, in particular LEDs, and/or tone signal generators, for example a buzzer. These two different types of signal generator are expediently alternately controlled in the event of a fault. As a result of this measure, energy is therefore always provided only for one signal type, with the result that the total energy consumption is thereby kept low. In this case, the supply module is expediently designed in such a manner that it is used to provide only a low power for supplying the monitoring module in such a manner that, in addition to supplying the microcontroller, only a single signal generator is adequately supplied with energy. Therefore, in the event of a fault, a changeover is alternately made between the buzzer and the LED. The use of LEDs is particularly advantageous from the points of view of energy.

The monitoring module described here is generally used to efficiently monitor a protective conductor in order to determine whether the latter is correctly connected. In this case, this monitoring module is preferably directly integrated in an electrical device component. In preferred alternatives, this device component is:
a) a plug for plugging into a socket,
b) a power distributor having a plurality of sockets, for example a socket strip, a cable drum etc.;
c) a separate monitoring module having a contact plug for connection to a socket. In this case, as mentioned under a), the separate monitoring module is either in the form of a plug itself, with the result that the entire monitoring module as such only needs to be plugged into a socket like a plug. Alternatively, it is a separate structural unit with its own housing which is to be connected to a socket via a connection cable. Such a monitoring module can be connected, for example, to the last socket in a supply section in order to check the entire supply section.
d) Alternatively, the monitoring module is directly part of an electrical household appliance, for example the so-called white goods, for example washing machines, tumble dryers, dishwashers, fridges etc., or else part of small electrical appliances, for example kettles etc.

In the case of integration in a power distributor having a plurality of sockets, provision is made, in particular, for the monitoring module to occupy, for example, the space of a conventional socket of the power distributor and to preferably be in the form of a modular insert which is inserted into the power distributor instead of a socket. The power distributor is, in particular, a socket strip.

If a fault, in particular the first fault, is detected, it is preferably only indicated without automatically causing an interruption in the power supply. In particular cases, however, automatic interruption of the power supply may also be provided. However, such an interruption is not desirable, in particular, in the case of office applications in which EDP devices are supplied, for example.

In one particularly preferred configuration, the monitoring module is integrated in a variable electrification system, in particular for offices. Such a variable electrification system usually comprises socket strips which can be connected to one another via an intermediate cable. In this case, contact plugs are usually arranged at both ends of the intermediate cable and are used to connect the individual socket strips to one another. These are preferably so-called type SV 16 contact plugs. The socket strips themselves have the commercially available plugs according to the respective national standard for normal household appliances; this is the Schuko plug in Germany. In the case of such a variable electrification system, the monitoring module is integrated, for example, inside such a socket strip or else is in the form of a plug for plugging into a (Schuko) socket of such a socket strip. However, it is preferably in the form of a separate monitoring module which is to be connected to a respective socket strip via a connection cable, the intermediate cable having the same type of contact plug as the intermediate cable of the electrification system. Therefore, the monitoring module is in the form of an add-on module of the variable electrification system and can be connected as an add-on unit like a socket strip of this electrification system. As a result of this particularly advantageous configuration, this monitoring module can be easily readily connected to existing electrification systems at a last socket at the end. As a result, the entire supply section up to this last socket is efficiently monitored for a correct protective conductor connection. Protective conductor monitoring can therefore be easily retrofitted.

A compact configuration is required, in particular, with regard to the configuration in which the monitoring module is itself in the form of a plug or else is arranged on a power distributor. Therefore, the components of the monitoring circuit are expediently configured in a sandwich structure in a space-saving manner. In this case, provision is made for the individual components to be arranged in a distributed manner on two printed circuit boards arranged above one another.

The special configurations of the protective conductor monitoring module which are described here, in particular the integration of the monitoring circuit in a plug, the configuration as an insert module inside a socket strip as a replacement for a socket and the configuration as a separate monitoring module which at the end to a last socket strip of a variable electrification system, can fundamentally also be implemented independently of the design having the features of the characterizing part of claim 1 and are considered to be independently inventive approaches. The submission of a divisional application for this is reserved.

One exemplary embodiment of the invention is explained in more detail below using the figures.

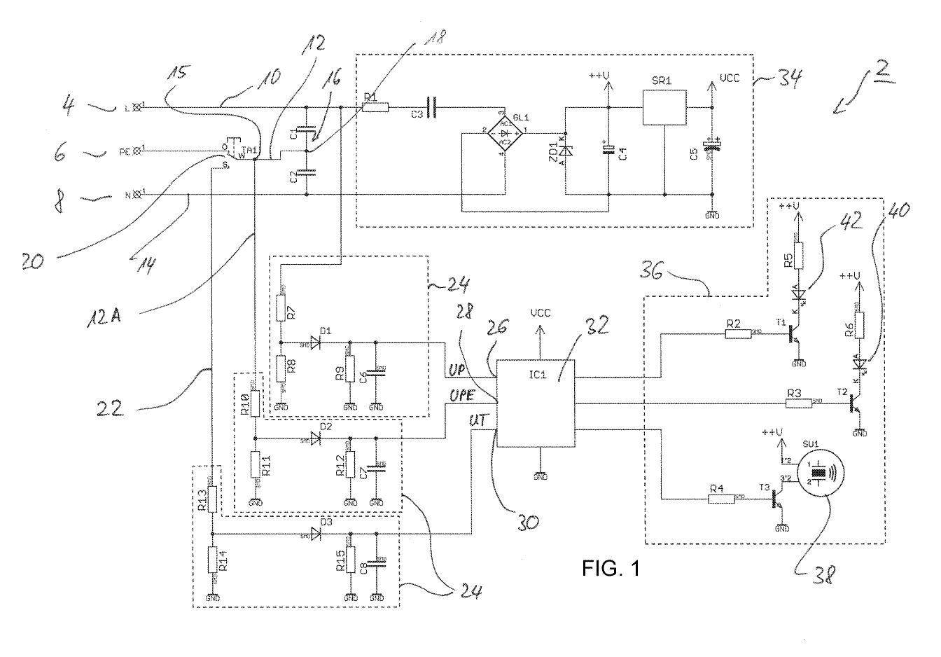

FIG. 1 shows a circuit diagram of a monitoring circuit of a monitoring

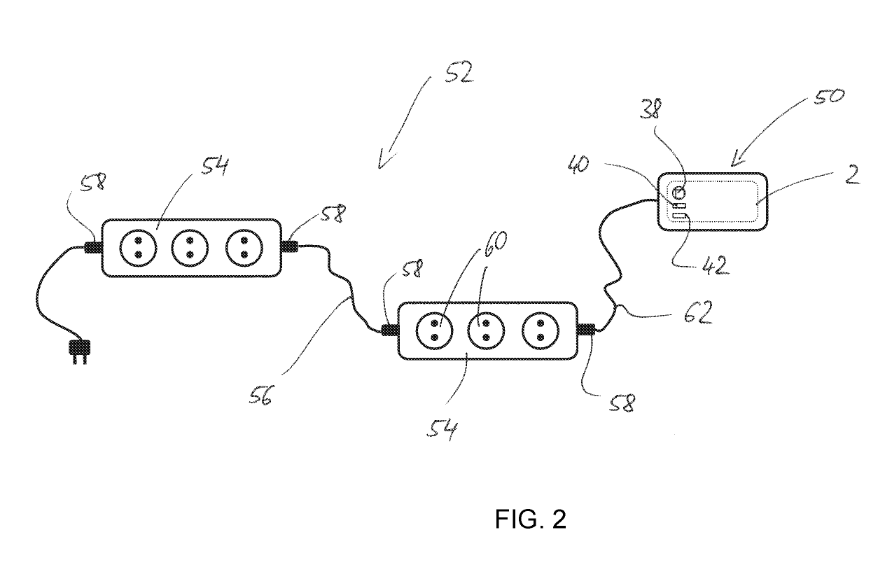

FIG. 2 shows a variable electrification system which is illustrated in a simplified manner and has a plurality of socket strips and a monitoring module.

The monitoring circuit 2 illustrated in FIG. 1 is generally used for protective conductor monitoring in order to check whether a protective conductor of a supply section for an electrical device, for example, has been interrupted. The symbols illustrated in FIG. 1 correspond to the conventional nomenclature for the individual electronic modules. In this case, the individual electronic modules of the same type are numbered consecutively.

On the input side, the monitoring circuit 2 has three connections, namely a phase connection 4 for connecting a phase conductor (not illustrated in any more detail here), a PE connection 6 for connecting a grounding conductor and a neutral connection 8 for connecting a neutral conductor. A phase path 10, a PE path 12 and a neutral path 14 adjoin the respective connection 4, 6, 8. A voltage divider 16 which is arranged as a capacitive voltage divider in the exemplary embodiment and has a center tap 18 is formed between the phase path 10 and the neutral path 14. The PE connection is connected to this center tap 18 via the PE path 12. In this case, an interrupter 20 in the form of a pushbutton is installed in the PE path 12. A section 12A of the PE path 12 branches away between the interrupter 20 and the center tap 18 at a PE tap 15.

If the interrupter 20 is actuated, the PE path 12 is interrupted in the region of the PE connection 6. At the same time, that section of the PE path 12 which is oriented to the center tap 18 is connected to a test path 22. If the interrupter 20 is actuated, the test path 22 is therefore connected to the center tap 18.

Furthermore, if necessary, the voltage applied to the phase connection 4 is tapped off at a section of the phase path 10 following the voltage divider 16. This voltage tapped off at the phase path 10, the voltage tapped off at the PE tap 15 and the voltage tapped off via the test path 22 are each preprocessed using a preprocessing module 24 and are made available to a phase input 26, a PE input 28 and a test input 30 of a microcontroller 32. A memory (not illustrated in any more detail here) and an evaluation logic unit for evaluating and assessing the different voltages applied to the inputs 26-30 are integrated in this microcontroller. These voltages are a preprocessed phase voltage UP at the phase input 26, a preprocessed PE voltage UPE at the PE input and a preprocessed test voltage UT at the test input.

The individual preprocessing modules 24 are used to preprocess the respective AC voltages for the microcontroller 32. For this purpose, the individual preprocessing modules 24 each have, on the input side, a voltage divider (R8, R7; R11, R10; and R14, R13) which is used to reduce the voltage value which has been tapped off to a voltage value suitable for the microcontroller. A respective center tap of these voltage dividers is connected to a filter unit which, in the exemplary embodiment, is respectively formed by a diode, a resistor and a capacitor.

The microcontroller 32 is supplied via a supply voltage VCC and measures the individual voltages UP, UPE, UT against a reference potential GND in each case. The supply voltage VCC is provided by a supply module 34 of the monitoring circuit 2. This obtains the supply voltage VCC from the mains voltage applied to the phase connection 4 or, in the event of polarity reversal, to the neutral connection 8. In addition to the supply voltage VCC for the microcontroller 32, the supply module 34 also generates a supply voltage V++ for a signal module 36. The supply module 34 has, inter alia, a rectifier GL1 and a voltage regulator SR1 as components.

On the output side, the signal module 36 is connected to the microcontroller 32 and is controlled by the latter. In the exemplary embodiment, it has a total of three signal generators, namely a tone generator 38 in the form of a buzzer and two luminous elements, namely a red LED 40 and a green LED 42. Further signal generators are preferably not provided.

In order to check whether a protective conductor is properly connected, the PE voltage UPE is fundamentally evaluated by the microcontroller 32 and is compared with voltage reference values RE1-RE3. Depending on the relationship between the measured PE voltage UPE and the voltage reference value RE1, RE2, RE3, different faults F1, F2, F3, F4 are identified by the microcontroller 32 and different fault signals S1, S2, S3 are output at the signal module 36 by means of appropriate control. In this case, different situations and faults are detected and identified by the monitoring circuit 2. These different operating states are summarized in the table below. In this case, the table does not claim to be complete. Depending on the implementation of a suitable evaluation logic unit in the microcontroller 32, yet further situations may also be identified and evaluated.

In the table, a distinction is made between three main operating modes, namely first of all the main operating mode “normal” in which a phase conductor is correctly connected to the phase connection 4, with the result that a (mains) supply voltage V is applied to the phase connection 4. This is characterized by the symbol V for the supply voltage in the column “L” for the phase connection 4. Within the main operating mode “normal”, a distinction is made between whether the protective conductor is correctly connected, is interrupted or was temporarily interrupted. This is accordingly indicated in the column “PE”.

In the second main operating mode, “phase to PE” is stated in the table in order to indicate those situations in which a voltage, in particular the supply voltage V, is applied to the PE connection 6. This is accordingly also indicated by the symbol V in the column PE in the table.

| | | | | | Voltage | | |
|---|---|---|---|---|---|---|---|
| | | | | | reference | | |
| | L | PE | N | UPE | value | Fault | Signal |
| Normal | | | | | | | |
| | V | OK | 0 | V1 < RE1 | RE1 | no | OK |
| | V | interrupted | 0 | V2 > V1 > RE1 | RE1 | F1 | S1 |
| | V | temporarily | 0 | temporarily | RE1 | F2 | S2 = |
| | | interrupted, | | V2 > V1 > R1; | | | (S1 + OK) |
| | | OK | | OK V1 < R1 | | | |
| | | again | | | | | |
| Phase to | | | | | | | |
| PE | | | | | | | |
| | V | V | 0 | V3 > V2 > R2 | RE2 | F3 | S3 |
| | 0 | V | 0 | V3 > V2 > R2 | RE2 | F3 | S3 |
| POLARITY | | | | | | | |
| REVERSAL | | | | | | | |
| a) without | 0 | OK | V | V3 > V2 > R2 | RE2 | F3 | S3 |
| detection | | | | | | | |
| b) with | 0 | OK | V | V3 > RE3 | RE3 = | no | OK |
| detection | | | | | new RE1 | | |
| | 0 | interrupted | V | V4 < V3 < RE3 | RE3 = | F1 | S1 |
| | | | | | new RE1 | | |

Finally, the situation “polarity reversal” is stated as the third main drive mode. In this case, a distinction is made between two variants, namely whether the monitoring circuit 2 actively detects this polarity reversal and takes it into account for the evaluation (with detection) or whether it identifies such polarity reversal as a fault F4 (without detection). This operating situation “polarity reversal” is generally characterized by the fact that the supply voltage V is applied to the neutral connection 8. This is indicated by the symbol V in the column “N” in the table.

In the table, the column “UPE” also indicates which PE voltage UPE is determined by the microcontroller 32, to be precise in relation to the different voltage reference values RE1, RE2, RE3. The individual PE voltages are stated as V1, V2, V3, V4 in this case.

Finally, the column “voltage reference value” states which is the respectively current voltage reference value to which the microcontroller 32 resorts. Finally, the column “fault” indicates whether and which fault F1-F4 is output and the column “signal” indicates which signal S1-S3 is output. In addition to the fault signals S1-S3, an OK signal is additionally also output and is characterized by the green LED 42 emitting light.

In conventional installation networks, the neutral conductor and the protective conductor are at the same potential and are therefore connected to one another on the input side of the installation. This simultaneously defines the reference potential. Apart from coupling-in effects, the neutral connection 8 and the PE connection 6 are therefore at at least approximately the same potential, the reference potential GND, if correctly connected.

In the normal mode, if correctly connected, the reference potential GND is present at the PE tap 15. Since the microcontroller 32 measures the PE voltage UPE against the reference potential GND, it does not measure a correlated voltage or at best measures a small correlated voltage value V1. In this case, the associated reference value RE1 is set to be very low and correlates to a voltage value of less than 10-20 volts at the center tap 18. If the text below refers to correlated voltages or voltage values, this takes into account the fact that voltage values which have been reduced by the preprocessing modules in comparison with the voltage values at the individual taps 15, 18 etc. are present at the inputs 28, 28, 30 of the microcontroller. If a voltage value V1 below this voltage reference value RE1 is therefore identified, this is interpreted as a correct state and an OK signal is output.

If the PE conductor is now interrupted, an intermediate voltage is present at the PE tap 15 between the supply voltage V and the neutral connection 8, which intermediate voltage is defined by the voltage divider 18 and can be tapped off at the center tap 18. This intermediate voltage has a voltage value which is approximately half the supply voltage V, for example. A considerably increased, correlated voltage is accordingly measured at the phase connection PE. This is characterized by V2 in the table. Since V2 is now considerably greater than the first voltage reference value RE1, this is identified as a first fault F1 and a first fault signal S1 is output. This is expressed, in particular, by alternately controlling the red LED 40 and the tone generator 38.

An OK situation is currently present if the protective conductor is temporarily interrupted. However, the fault which previously occurred is stored and noted inside the microcontroller 32. This only temporary fault which is currently no longer present is evaluated as a second fault F2 and a second fault signal S2 is output. This is composed, for example, of the normal fault signal S1 combined with the OK fault signal. Provision is specifically made for both the red LED 40 and the green LED 42 to be activated, in which case the red LED flashes, for example.

If voltage is applied to the PE connection 6, a voltage which is correlated to the supply voltage V and has the voltage value V3 is measured as the PE voltage UPE. This is again considerably above the voltage value V2, with the result that this situation again needs to be clearly identified. For this purpose, a further voltage reference value RE2 is stored, the exceeding of which identifies this fault F3, and a corresponding fault signal S3 is output. This is expressed, for example, in rapid flashing of the red LED 40 combined with a special tone via the tone generator 38.

The situation in which a voltage value is present at the PE connection occurs, for example, if a grounded housing of an electrical device is connected to the phase conductor. In this case, the supply voltage is therefore usually still available via the phase connection 4 and proper operation via the supply module 34 is ensured. If the phase conductor is incorrectly connected to the PE connection 6 of the electrical device, the monitoring circuit 2 also has a battery, in particular a rechargeable battery (not illustrated in any more detail here), which in this case then provides the supply voltage for the microcontroller 32 and the signal module 36.

In the event of polarity reversal, the supply V is applied to the neutral connection 8. If the protective conductor is correctly connected, this state initially cannot be distinguished from the situation in which the supply voltage V is applied to the phase connection 4 according to a first embodiment variant. In this case, the microcontroller 32 measures the reference potential applied to the PE input 28 against the supply voltage V, with the result that it again measures the voltage value V3. The identical fault F3 as that described above is therefore detected as the fourth fault F4. In this embodiment variant, in order to distinguish between the two faults F3 and F4, it is necessary for the user to rotate the plug for the electrical device or else for a socket strip through 180° once, for example. In this case, if the protective conductor is correctly connected, the normal operating situation will be established and the OK signal will appear. If the fault remains, this is a serious fault which should be immediately eliminated. The corresponding fault signal S3 is combined with a loud/fast tone sequence, for example.

In an alternative embodiment variant, an evaluation logic unit which detects such polarity reversal is stored. For this purpose, the voltage applied to the phase connection 4, for example, is evaluated via the phase input 26. This makes it possible for the microcontroller 32 to detect whether or not there is polarity reversal. If the microcontroller detects that there is polarity reversal, it will select a modified voltage reference value RE3 instead of the voltage reference value RE1. Since the microcontroller 32 measures the PE voltage UPE against the supply voltage V in this case, the voltage value V3 is therefore present. This correlates approximately to the supply voltage V. As long as this is above the modified reference value RE3, the state is OK.

If the protective conductor is interrupted, an intermediate voltage of the center tap 18 is applied to the PE input 28, with the result that the measured PE voltage UPE is reduced, in comparison with V3, to a value of V4 which is below the voltage reference value RE3. The voltage reference value RE3 correlates, for example, to the supply voltage minus a few 10 volts. This is then again identified as a first fault F1 and the first fault signal S1 is output.

As a further essential function, the monitoring circuit 2 also has a test function. This is carried out by manually actuating the interrupter 20. An interruption in the protective conductor is therefore simulated upon this actuation. As a result, the first fault F1 is actively caused and is detected by the microcontroller 32. At the same time, however, as a result of the connection to the test input 30 via the test path 22, the PE voltage UPE is also measured as the test voltage UT at this test input 30. As a result, the microcontroller 32 detects the actuation of the interrupter 2 and in this case does not store the identified fault F1 in the memory. At the same time, it outputs a corresponding test signal in order to indicate that it is functional.

The monitoring circuit 2 described with respect to FIG. 1 can be fundamentally integrated in a wide variety of electrical devices in order to monitor the latter.

In one particularly preferred configuration, the monitoring circuit 2 is integrated in an independent monitoring module 50 which forms a separate structural unit, as is illustrated, by way of example, in FIG. 2 using a variable electrification system 52. Such an electrification system is usually used in offices and usually consists of a multiplicity of socket strips 54 which can be connected to one another by means of intermediate cables 56. In this case, the intermediate cables 56 each have a contact plug 58 at the end. Each socket strip 54 therefore has a corresponding socket for receiving such a contact plug 58 on both the input side and the output side on opposite end walls, for example. These contact plugs 58 are a plug type which differs from the normal sockets 60 of the socket strip 54, for example of the type SV18. The sockets 60 are the customary sockets, Schuko sockets in Germany.

In the exemplary embodiment in FIG. 2, the monitoring module 50 is connected to the last socket strip 54 of a supply section via a connection cable 62. For this purpose, a contact plug 58 is again formed on the connection cable 62.

The monitoring module 50 is therefore formed overall by a housing having the monitoring circuit 2 integrated therein and the connection cable 62 having the contact plug 58 at the end. This monitoring module 50 preferably does not have any further components.

As an alternative to the embodiment variant illustrated in FIG. 2, the monitoring module 50 is itself in the form of a plug which can be plugged into a socket 60 in a preferred configuration. In this case, the entire monitoring module 50 is therefore in the form of a plug-in plug.

In another embodiment variant, the monitoring module 50 is integrated in a socket strip 54. For example, it occupies the installation space of one of the sockets 60 in this case.

In the case of integration in a plug, it should be emphasized, in particular, that this may be a connection plug for the electrical device, for example a washing machine etc. In this case, protective conductor monitoring is therefore automatically carried out by plugging in the washing machine.

Finally, it is also possible for the monitoring module 50 to be in the form of an adapter which is intended to be plugged into a socket 60 and, at the same time, itself forms a socket 60. The monitoring module 50 can therefore itself be plugged into a socket and is also used to supply an electrical device.

The individual components of the monitoring circuit 2 which are illustrated in FIG. 1 are preferably arranged in a manner distributed on two or more printed circuit boards which are placed above one another in a sandwich structure with respect to one another. This is provided, in particular, in the case of integration in a plug.

### LIST OF REFERENCE SYMBOLS

2 Monitoring circuit

4 Phase connection

6 PE connection

8 Neutral connection

10 Phase path

12 PE path

12A Section

14 Neutral path

15 PE tap

16 Voltage divider

18 Center tap

20 Interrupter

22 Test path

24 Preprocessing module

26 Phase input

28 PE input

30 Test input

32 Microcontroller

34 Supply module

36 Signal module

38 Tone generator

40 Red LED

42 Green LED

50 Monitoring module

52 Variable electrification system

54 Socket strip

56 Intermediate cable

58 Contact plug

60 Socket

62 Connection cable

UP Phase voltage

UPE UP voltage

UT Test voltage

GND Reference potential

RE1 First voltage reference value

RE2 Second voltage reference value

RE3 Modified voltage reference value

F1 First fault

F2 Second fault

F3 Third fault

F4 Fourth fault

S1 First fault signal

S2 Second fault signal

S3 Third fault signal

V Supply voltage

V1, V1, V3 Voltage values

1-15. (canceled)

16. A monitoring module for protective conductor monitoring, comprising a monitoring circuit for monitoring whether a protective conductor is properly connected, in which case, if a protective conductor interruption is detected, the monitoring circuit identifies this as a first fault and outputs a first fault signal,
characterized in that
the monitoring circuit is designed to store the first fault and is also designed in such a manner that, in the event of an only temporary protective conductor interruption which is no longer present, it identifies this as a second temporary fault, and a second fault signal which differs from the first fault signal is output,
the monitoring circuit comprises a microcontroller for identifying at least the first fault,
the monitoring circuit has, on the input side, a phase connection for a phase conductor with an adjoining phase path, a PE connection for the protective conductor to be monitored with an adjoining PE path and a neutral connection for a neutral conductor with an adjoining neutral path, and the monitoring circuit is designed to check a PE voltage applied to the PE path for the presence of at least the first fault and has the microcontroller having a PE input for this purpose, and the microcontroller is designed to compare the PE voltage with a first voltage reference value, in which case a voltage divider is formed, in particular, between the phase path and the neutral path for this purpose, the PE path is connected to a center tap of the voltage divider, and the voltage present at the center tap is evaluated as the PE voltage,
the monitoring circuit has, for the purpose of checking the functionality, an interrupter which can be manually actuated and, for the purpose of simulating an interrupted protective conductor, is designed to temporarily interrupt the PE path,
the evaluation unit has a test input which is connected to the interrupter via a test path in such a manner that a connection between the test path and the center tap is established if the interrupter is actuated,
the evaluation unit is designed in such a manner that it distinguishes between the first fault of an interrupted protective conductor and a further fault, namely optionally a third fault, in which a voltage is applied to the PE connection, or a fourth fault, in which the polarity of the phase connection and of the neutral connection is reversed,
for the further fault, the evaluation unit stores a second voltage reference value, the exceeding of which indicates the further fault, the second voltage reference value being greater than the first voltage reference value, or
as an alternative to identifying the further fault, the evaluation unit is designed to identify, by checking the voltage value present at the phase connection or neutral connection, whether the polarity of the phase connection and of the neutral connection is reversed and in this case uses a modified voltage reference value as the first voltage reference value for monitoring for the first fault.

17. A monitoring module for protective conductor monitoring, comprising a monitoring circuit for monitoring whether a protective conductor is properly connected, in which case, if a protective conductor interruption is detected, the monitoring circuit identifies this as a first fault and outputs a first fault signal,
characterized in that
the monitoring circuit is designed to store the first fault and is also designed in such a manner that, in the event of an only temporary protective conductor interruption which is no longer present, it identifies this as a second temporary fault, and a second fault signal which differs from the first fault signal is output.

18. The monitoring module as claimed in claim 17,
characterized in that
the monitoring circuit is designed in such a manner that the temporary fault is permanently stored until a manual reset.

19. The monitoring module as claimed in claim 17,
characterized in that
the monitoring circuit comprises a microcontroller for identifying at least the first fault.

20. The monitoring module as claimed in claim 17,
characterized in that
the monitoring circuit has, on the input side, a phase connection for a phase conductor with an adjoining phase path, a PE connection for the protective conductor to be monitored with an adjoining PE path and a neutral connection for a neutral conductor with an adjoining neutral path, and the monitoring circuit is designed to check a PE voltage applied to the PE path for the presence of at least the first fault and has an evaluation unit having a PE input for this purpose, and the evaluation unit is designed to compare the PE voltage with a first voltage reference value, in which case a voltage divider is formed, in particular, between the phase path and the neutral path for this purpose, the PE path is connected to a center tap of the voltage divider, and the voltage present at the center tap is evaluated as the PE voltage.

21. The monitoring module as claimed in claim 17,
characterized in that
the monitoring circuit has, for the purpose of checking the functionality, an interrupter which can be manually actuated and, for the purpose of simulating an interrupted protective conductor, is designed to temporarily interrupt the PE path.

22. The monitoring module as claimed in claim 20,
characterized in that
the evaluation unit has a test input which is connected to the interrupter via a test path in such a manner that a connection between the test path and the center tap is established if the interrupter is actuated.

23. The monitoring module as claimed in claim 17,
characterized in that
the evaluation unit is designed in such a manner that it distinguishes between the first fault of an interrupted protective conductor and a further fault, namely either a third fault, in which a voltage is applied to the PE connection, or a fourth fault, in which the polarity of the phase connection and of the neutral connection is reversed.

24. The monitoring module as claimed in claim 23,
characterized in that
for the further fault, the evaluation unit stores a second voltage reference value, the exceeding of which indicates the further fault, the second voltage reference value being greater than the first voltage reference value.

25. The monitoring module as claimed in claim 17,
characterized in that
the evaluation unit is designed to identify, by checking the voltage value present at the phase connection or neutral connection, whether the polarity of the phase connection and of the neutral connection is reversed and in this case uses a modified voltage reference value as the first voltage reference value for monitoring for the first fault.

26. The monitoring module as claimed in claim 17,
characterized in that
the evaluation unit is supplied with voltage during normal operation via a mains voltage and a battery is additionally provided as the emergency power supply.

27. The monitoring module as claimed in claim 17,
characterized in that
it has a plurality of signal generators of different types, in particular LEDs and/or a tone generator, and in that these signal generators are alternately controlled in the event of a fault.

28. The monitoring module, in particular as claimed in claim 17, for protective conductor monitoring, comprising a monitoring circuit for monitoring whether a protective conductor is properly connected, in which case, if a protective conductor interruption is detected, the monitoring circuit identifies this as a first fault and outputs a first fault signal,
characterized in that
it is integrated in an electrical device component which is optionally in the form of
a plug for plugging into a socket,
a power distributor having a plurality of sockets,
a separate monitoring module having a contact plug for connection to a socket,
an electrical household appliance.

29. The monitoring module as claimed in claim 28,
characterized in that
if designed as a separate monitoring module, it is part of a variable electrification system, in particular for offices, which system comprises socket strips which can be connected to one another via an intermediate cable, the intermediate cable having, at the two ends, a contact plug for connection to a respective socket strip, in that the separate monitoring module can be connected to a socket strip via a connection cable and a contact plug, the contact plug of the intermediate cable preferably being of the same type as the contact plug of the connection cable.

30. The monitoring module as claimed in claim 16,
characterized in that
the individual components of the monitoring circuit are arranged in a sandwich structure in a manner distributed on at least two levels arranged above one another.
